(19) United States
(12) Patent Application Publication
(10) Pub. No.: US 2021/0359068 A1
(43) Pub. Date: Nov. 18, 2021

(54) ORGANIC LIGHT EMITTING DIODE DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Weijie HUANG, Wuhan, Hubei (CN); Qi CAO, Wuhan, Hubei (CN)

(21) Appl. No.: 16/347,307

(22) PCT Filed: Mar. 12, 2019
(86) PCT No.: PCT/CN2019/077821

§ 371 Date: May 3, 2019

(30) Foreign Application Priority Data
Dec. 18, 2018 (CN) 201811548965.9

(51) Int. Cl. H01L 27/32

(52) U.S. Cl. CPC H01L 27/3276; H01L 27/3288

(57) ABSTRACT

Provided is an organic light emitting diode display panel, including: a substrate, a plurality of signal lines and at least one spare line disposed on the substrate, wherein the signal lines are at a different layer from the spare line; a plurality of preset connection points are disposed on the spare line, and a projection of any of the signal lines on the substrate overlaps a projection of the two preset connection points on the substrate, and when any of the signal lines is disconnected, the disconnected signal line is electrically connected to the spare line via the preset connection points, so that the disconnected signal line works normally through the spare line.

### FIELD OF THE INVENTION

The present application relates to a display technology field, and more particularly to an organic light emitting diode display panel.

### BACKGROUND OF THE INVENTION

As a current type light emitting device, Organic Light Emitting Diode (OLED) is widely used because of properties of self-illumination, rich color, fast response speed, wide viewing angle, light weight and flexible display, and thus draws many attentions.

In general OLED display panels, since the distance between the signal lines is small, there is a risk that the signal lines will be broken during the manufacturing process. When the signal line is broken, it will affect the display quality of the OLED display panel, which will result in dropping the yield of the product and lowering the shipment rate of the OLED display panel.

### SUMMARY OF THE INVENTION

The technical problem solved by the present application is how to improve the display quality of the organic light emitting diode display panel, thereby improving the product yield of the organic light emitting diode display panel, and improving the shipment rate of the organic light emitting diode display panel.

First, the present application provides an organic light emitting diode display panel, including:

a substrate, a plurality of signal lines and at least one spare line disposed on the substrate, wherein the signal lines are at a different layer from the spare line;

wherein a projection of the spare line on the substrate possesses at least two overlapping points with a projection of any of the signal lines on the substrate;

the spare signal line is a ring structure or a semi-ring structure; and

an insulating layer is disposed between the signal lines and the spare line to insulate the signal lines from the spare line.

In the organic light emitting diode display panel provided by the present application, a plurality of preset connection points are disposed on the spare line, and the projection of any of the signal lines on the substrate overlaps a projection of the two preset connection points on the substrate, and when any of the signal lines is disconnected, the disconnected signal line is electrically connected to the spare line via the preset connection points at the overlapping points, so that the disconnected signal line works normally through the spare line.

In the organic light emitting diode display panel provided by the present application, the spare line includes a first portion and a second portion, and a projection of each of the signal lines on the substrate intersects the first portion and the second portion, and the first portion and the second portion are disposed opposite to each other.

In the organic light emitting diode display panel provided by the present application, the preset connection points include a plurality of first sub preset connection points and a plurality of second sub preset connection points;

the first sub preset connection points are disposed on the first portion along an arrangement direction of the signal lines, and the second sub preset connection points are disposed on the second portion along an arrangement direction of the signal lines.

In the organic light emitting diode display panel provided by the present application, the spare line further includes a connection portion for connecting the first portion and the second portion, and the connection portion includes a first sub connection portion and a second sub connection portion, and the first sub connection portion and the second sub connection portion are respectively located on two sides of the plurality of signal lines.

In the organic light emitting diode display panel provided by the present application, the spare line further includes a connection portion for connecting the first portion and the second portion, and the connection portion is located on either side of the plurality of signal lines.

In the organic light emitting diode display panel provided by the present application, a number of the spare lines is greater than or equal to half a number of the signal lines.

In the organic light emitting diode display panel provided by the present application, the plurality of the spare lines are disposed at a same layer and are insulated from one another.

In the organic light emitting diode display panel provided by the present application, the plurality of the spare lines is disposed at different layers.

Second, the present application provides an organic light emitting diode display panel, including:

a substrate, a plurality of signal lines and at least one spare line disposed on the substrate, wherein the signal lines are at a different layer from the spare line;

wherein a projection of the spare line on the substrate possesses at least two overlapping points with a projection of any of the signal lines on the substrate.

In the organic light emitting diode display panel provided by the present application, a plurality of preset connection points are disposed on the spare line, and the projection of any of the signal lines on the substrate overlaps a projection of the two preset connection points on the substrate, and when any of the signal lines is disconnected, the disconnected signal line is electrically connected to the spare line via the preset connection points at the overlapping points, so that the disconnected signal line works normally through the spare line.

In the organic light emitting diode display panel provided by the present application, the spare signal line is a ring structure or a semi-ring structure.

In the organic light emitting diode display panel provided by the present application, the spare line includes a first portion and a second portion, and a projection of each of the signal lines on the substrate intersects the first portion and the second portion, and the first portion and the second portion are disposed opposite to each other.

In the organic light emitting diode display panel provided by the present application, the preset connection points include a plurality of first sub preset connection points and a plurality of second sub preset connection points; wherein the first sub preset connection points are disposed on the first portion along an arrangement direction of the signal lines, and the second sub preset connection points are disposed on the second portion along an arrangement direction of the signal lines.

In the organic light emitting diode display panel provided by the present application, the spare line further includes a connection portion for connecting the first portion and the second portion, and the connection portion includes a first sub connection portion and a second sub connection portion, and the first sub connection portion and the second sub connection portion are respectively located on two sides of the plurality of signal lines.

In the organic light emitting diode display panel provided by the present application, the spare line further includes a connection portion for connecting the first portion and the second portion, and the connection portion is located on either side of the plurality of signal lines.

In the organic light emitting diode display panel provided by the present application, an insulating layer is disposed between the signal lines and the spare line to insulate the signal lines from the spare line.

In the organic light emitting diode display panel provided by the present application, a number of the spare lines is greater than or equal to half a number of the signal lines.

In the organic light emitting diode display panel provided by the present application, the plurality of the spare lines are disposed at a same layer and are insulated from one another.

In the organic light emitting diode display panel provided by the present application, the plurality of the spare lines is disposed at different layers.

In the organic light emitting diode display panel provided by the present application, projections of the spare lines on the substrate overlap.

In the organic light emitting diode display panel provided by the present application, when any of the signal lines is disconnected, the disconnected signal line can be connected to the spare line by laser welding.

In the organic light emitting diode display panel provided by the present application, the cutting point corresponding to the disconnected signal line on the spare line may be cut by laser cutting, so that the disconnected signal line works normally through the spare line.

In the organic light emitting diode display panel provided by the present application, a projection of the cutting point on the substrate is on one side of the projection of the signal line on the substrate.

By providing at least one spare line on the substrate, when any of the signal lines is disconnected, the disconnected signal line works normally through the spare line to achieve the objective of improving the display quality of the organic light emitting diode display panel, thereby improving the product yield of the organic light emitting diode display panel, and improving the shipment rate of the organic light emitting diode display panel.

### BRIEF DESCRIPTION OF THE DRAWINGS

In order to more clearly illustrate the embodiments of the present application, the following figures will be described in the embodiments are briefly introduced. It is obvious that the drawings are merely some embodiments of the present application, those of ordinary skill in this field can obtain other figures according to these figures without paying the premise.

FIG. 1 is a plan view diagram of an organic light emitting diode (OLED) display panel provided by the present application;

FIG. 2 is a structural diagram of an OLED display panel provided by the present application;

FIG. 3 is an enlarged view diagram of a portion A of the first embodiment of the OLED display panel provided by the present application;

FIG. 4 is an enlarged view diagram of a portion A of the OLED display panel shown in FIG. 3 in a state in which one signal line is in a disconnected state;

FIG. 5 is an enlarged view diagram of a portion A of the OLED display panel shown in FIG. 3 in a state in which two signal lines are in a disconnected state;

FIG. 6 is an enlarged view diagram of a portion A of the second embodiment of the OLED display panel provided by the present application;

FIG. 7 is an enlarged view diagram of a portion A of the OLED display panel shown in FIG. 6 in a state in which one signal line is in a disconnected state;

FIG. 8 is an enlarged view diagram of a portion A of the third embodiment of the OLED display panel provided by the present application.

### DETAILED DESCRIPTION OF PREFERRED EMBODIMENTS

The embodiments of the present application are described in detail below, and the examples of the embodiments are illustrated in the drawings, wherein the same or similar reference numerals are used to refer to the same or similar elements or elements having the same or similar functions. The embodiments described below with reference to the drawings are intended to be illustrative for the present application and are not to be construed as limitation.

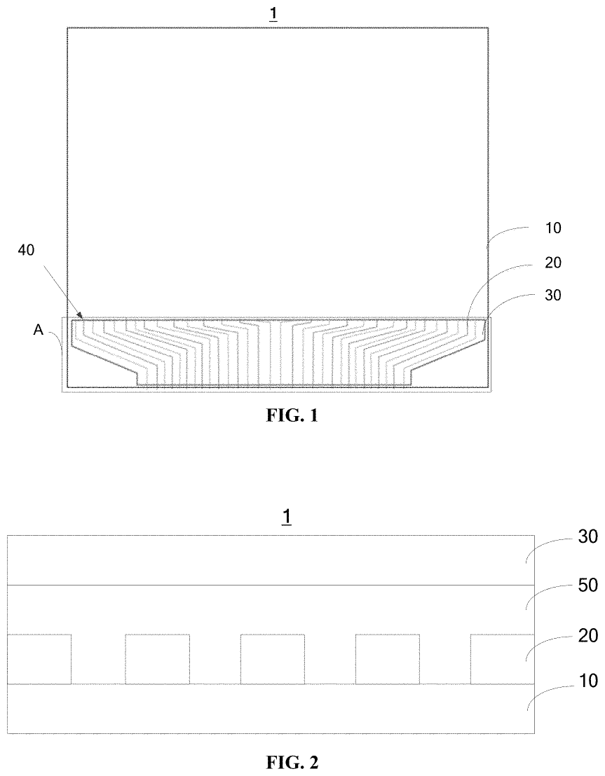

Please refer to FIG. 1. FIG. 1 is a plan view diagram of an organic light emitting diode (OLED) display panel provided by the present application.

The present application provides an organic light emitting diode (OLED) display panel 1, including: a substrate 10, a plurality of signal lines 20 and at least one spare line 30 disposed on the substrate 10, wherein the signal lines 20 are at a different layer from the spare line 30. A projection of the spare line 30 on the substrate 10 possesses at least two overlapping points with a projection of any of the signal lines 20 on the substrate 10.

Please continue to refer to FIG. 1, a plurality of preset connection points 40 are disposed on the spare line 30, and a projection of any of the signal lines 20 on the substrate 10 overlaps a projection of the two preset connection points 40 on the substrate 10, and when any of the signal lines 20 is disconnected, the disconnected signal line 20 is electrically connected to the spare line 30 via the preset connection points 40, so that the disconnected signal line 20 works normally through the spare line 30.

The substrate 10 may be a light emitting substrate formed with organic light emitting diode elements, and the substrate 10 may include various circuit structures and/or substrate structures according to actual requirements. According to the actual situation, there is no limit here. The signal line 20 may be a data line or a scan line, or may be a signal line on the substrate 10 for transmitting other signals. The spare line 30 may be a metal trace. A number of the spare lines 30 may be one or multiple, and may be set according to actual conditions. Any of the spare lines 30 is located at different layer from the signal lines 20 as shown in FIG. 2. An insulating layer 50 is disposed between the signal lines 20 and the spare line 30 to insulate the signal lines 20 from the spare line 30. In order to prevent crosstalk between the signal lines 20 and the spare line 30, the signal lines 20 and the spare line 30 are located at different layers, and an insulating layer 50 is disposed between the signal lines 20 and the spare line 30 to insulate the signal lines 20 from the spare line 30. A material of the insulating layer 50 may be an organic material or an inorganic material.

Specifically, the preset connection point 40 may be a point at which the spare line 30 functions as a marker. When a signal line 20 is disconnected, the disconnected signal line 20 is electrically connected to the spare line 30 via the preset connection point 40, thereby restoring normal operation.

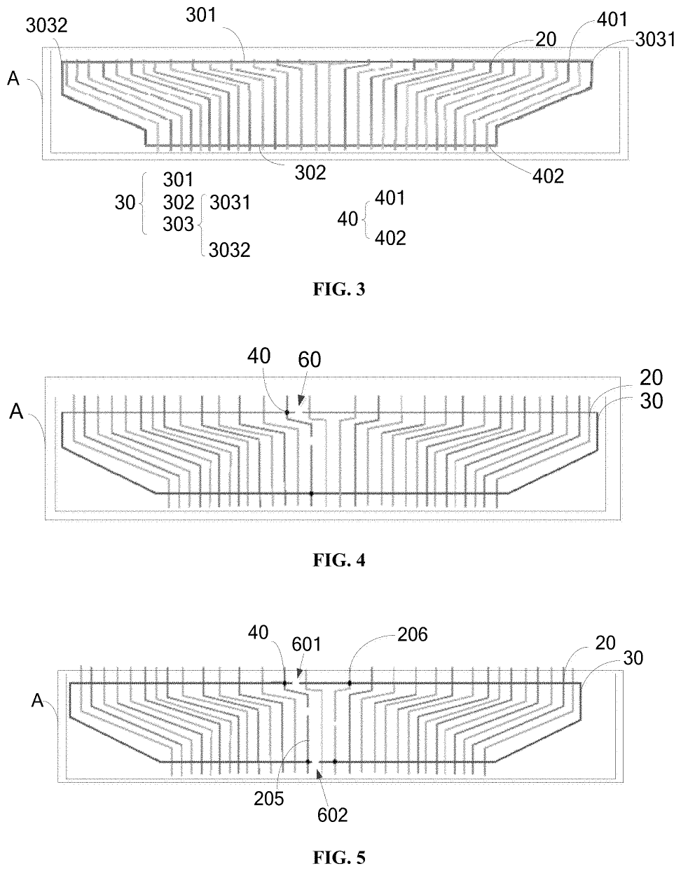

In some embodiments, the spare line 30 is a ring structure. Please refer to FIG. 3. FIG. 3 is an enlarged view diagram of a portion A of the first embodiment of the OLED display panel provided by the present application. The spare line 30 includes a first portion 301 and a second portion 302, and a projection of each of the signal lines 20 on the substrate 10 intersects the first portion 301 and the second portion 302, and the first portion 301 and the second portion 302 are disposed opposite to each other.

The spare line 30 includes the first portion 301 and the second portion 302, which are disposed opposite to each other. The projection of each of the signal lines 20 on the substrate 10 intersects the first portion 301 and the second portion 302. For instance, when only one spare line 30 is provided, the projection of any of the signal lines 20 on the substrate 10 intersects a projection of the first portion 301 on the substrate 10, and the projection of any of the signal lines 20 on the substrate 10 intersects a projection of the second portion 302 on the substrate 10. For another instance, when a plurality of spare lines 30 is provided, the projection of any of the signal lines 20 on the substrate 10 intersects the projection of any of the first portions 301 on the substrate 10, and the projection of any of the signal lines 20 on the substrate 10 intersects the projection of any of the second portions 302 on the substrate 10.

Please continue referring to FIG. 3. The preset connection points 40 include a plurality of first sub preset connection points 401 and a plurality of second sub preset connection points 402; wherein the first sub preset connection points 401 are disposed on the first portion 301 along an arrangement direction of the signal lines 20, and the second sub preset connection points 402 are disposed on the second portion 302 along the arrangement direction of the signal lines 20.

Specifically, the first sub preset connection points 401 are disposed on the first portion 301 along the arrangement direction of the signal lines 20 and the second sub preset connection points 402 are disposed on the second portion 302 along the arrangement direction of the signal lines 20, so that the spare line 30 can be electrically connected to the disconnected signal line 20.

In some embodiments, the spare line 30 further includes a connection portion 303 for connecting the first portion 301 and the second portion 302. The connection portion 303 includes a first sub connection portion 3031 and a second sub connection portion 3032, and the first sub connection portion 3031 and the second sub connection portion 3032 are respectively located on two sides of the plurality of signal lines 20. The projections of the first sub connection portion 3031, the second sub connection portion 3032, the first portion 301 and the second portion 302 on the substrate 10 at least partially cover the signal lines 20.

When any of the signal lines 20 is disconnected, the disconnected signal line 20 can be connected to the spare line 30 by laser welding for instance, so that the disconnected signal line 20 works normally. Then, the cutting point corresponding to the disconnected signal line 20 on the spare line 30 may be cut by laser cutting, so that the disconnected signal line 20 works normally through the spare line 30.

For instance, please refer to FIG. 4. FIG. 4 is an enlarged view diagram of a portion A of the OLED display panel shown in FIG. 3 in a state in which one signal line is in a disconnected state. When one signal line 20 is disconnected, the substrate 10 is transferred to a laser cutting machine, and the cutting point 60 corresponding to the disconnected signal line 20 on the spare line 30 is cut by laser cutting, and then the disconnected signal line 20 is connected to the spare line 30 by laser welding. As welding, the laser first fuses the preset connection point 40 on the spare line 30, and then forms a via hole in the insulating layer 50. The spare line 30 is electrically connected to the signal line 20 through the via hole, so that the disconnected signal line 20 is electrically connected to the spare line 30. Finally, the cutting point 60 corresponding to the disconnected signal line 20 on the spare line 30 is cut by laser cutting, and a projection of the cutting point 60 on the substrate 10 is on one side of the projection of the signal line 20 on the substrate 10.

For another instance, please refer to FIG. 5. FIG. 5 is an enlarged view diagram of a portion A of the OLED display panel shown in FIG. 3 in a state in which two signal lines are in a disconnected state. When two signal lines 20 are disconnected, the signal line 205 and the signal line 206 are both disconnected at this time. First, the substrate 10 is still transferred to a laser cutting machine, the cutting point 601 corresponding to the disconnected signal line 205 on the spare line 30 is cut by laser cutting, and the cutting point 602 corresponding to the disconnected signal line 206 on the spare line 30 is cut by laser cutting. Then, the disconnected signal line 205 is connected to the spare line 30 by laser welding, and meanwhile, the disconnected signal line 206 is connected to the spare line 30 by laser welding. As welding, the laser first fuses the preset connection point 40 on the spare line 30, and then forms a via hole in the insulating layer 50. The spare line 30 is electrically connected to the signal line 205 through the via hole and the spare line 30 is electrically connected to the signal line 206 through the via hole, so that the disconnected signal line 205 and the disconnected signal line 206 are electrically connected to the spare line 30. Finally, the cutting point 601 corresponding to the disconnected signal line 205 and the cutting point 602 corresponding to the disconnected signal line 206 on the spare line 30 are cut by laser cutting, and projections of the cutting point 601 and the cutting point 602 on the substrate 10 are between the projections of the signal line 205 and the signal line 206 on the substrate 10.

In some embodiments, the spare line 30 further includes a connection portion 304 for connecting the first portion 301 and the second portion 302, and the connection portion 304 is located on either side of the plurality of signal lines 20.

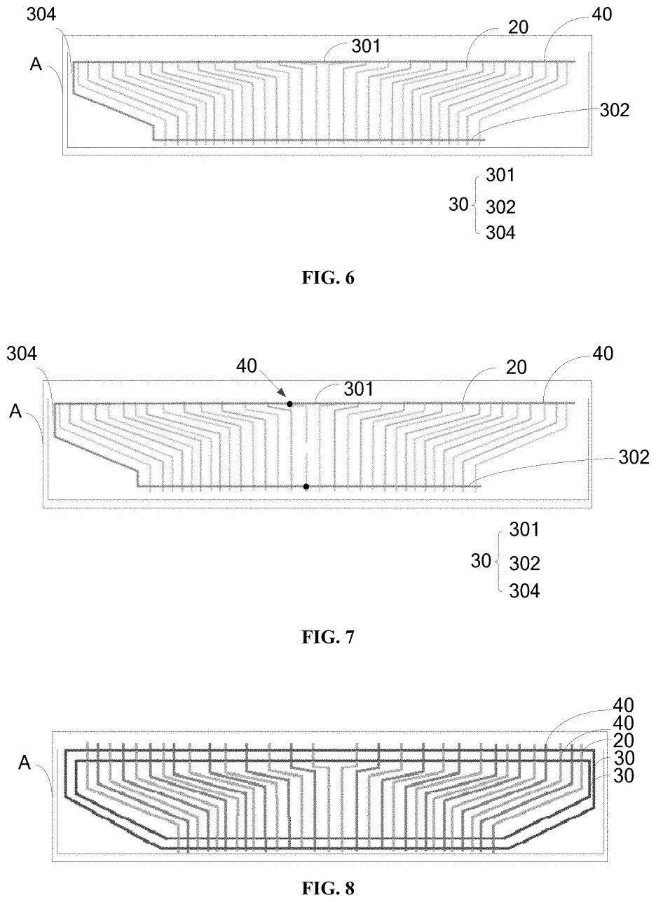

Please refer to FIG. 6. FIG. 6 is an enlarged view diagram of a portion A of the second embodiment of the OLED display panel provided by the present application. The OLED display panel 1 of FIG. 6 differs from the OLED display panel 1 of FIG. 3 in that the spare line 30 is a semi-annular structure. The spare line 30 includes a first portion 301, a second portion 302 and a connection portion 304 for connecting the first portion 301 and the second portion 302. A projection of each of the signal lines 20 on the substrate 10 intersects the first portion 301 and the second portion 302, and the first portion 301 and the second portion 302 are disposed opposite to each other. The connection portion 304 is located on either side of the plurality of signal lines 20.

When any of the signal lines 20 is disconnected, the disconnected signal line 20 can be connected to the spare line 30 by laser welding for instance, so that the disconnected signal line 20 works normally.

In some embodiments, please refer to FIG. 7. FIG. 7 is an enlarged view diagram of a portion A of the OLED display panel shown in FIG. 6 in a state in which one signal line is in a disconnected state. Specifically, when only one signal line 20 is disconnected, only the signal line 20 and the spare line 30 need to be welded without laser cutting the spare line 30, which further improves efficiency.

For instance, when only one signal line 20 is disconnected, the substrate 10 is transferred to a laser cutting machine, and the cutting point 60 corresponding to the disconnected signal line 20 on the spare line 30 is cut by laser cutting, and then the disconnected signal line 20 is connected to the spare line 30 by laser welding. As welding, the laser first fuses the preset connection point 40 on the spare line 30, and then forms a via hole in the insulating layer 50. The spare line 30 is electrically connected to the signal line 20 through the via hole, so that the disconnected signal line 20 is electrically connected to the spare line 30, so that the disconnected signal line 20 works normally.

In some embodiments, the number of signal lines 20 is equal to twice the number of spare lines 30.

Since one spare line 30 can repair up to two disconnected signal lines 20 at most, as the number of signal lines 20 is equal to twice the number of spare lines 30, it can be ensured that each of the signal lines 20 does not cause a problem of deterioration in display quality of the OLED display panel due to disconnection, and also facilitates wiring of the spare line 30.

In some embodiments, the plurality of the spare lines 30 is disposed at a same layer and insulated from one another.

In some embodiments, the plurality of the spare lines 30 are disposed at different layers, and projections of the spare lines 30 on the substrate 10 all overlap.

When the plurality of the spare lines 30 are disposed at different layers, the projections of the spare lines 30 on the substrate 10 all overlap. Therefore, this doe not only prevent crosstalk between adjacent spare lines, but also improves the stability of the OLED display panel, and since the spare lines 30 are all located at different layers, it is advantageous to realize a narrow frame OLED display panel.

Please refer to FIG. 8. FIG. 8 is an enlarged view diagram of a portion A of the third embodiment of the OLED display panel provided by the present application. For the OLED panel, three signal lines 20 are disconnected, then one spare line 30 is added. For the connection method of the spare lines 30 and the three disconnected signal lines 20, refer to the previous embodiments, and details are not described herein, again.

By providing at least one spare line 30 on the substrate in the present application, when any of the signal lines 20 is disconnected, the disconnected signal line 20 can work normally through the spare line 30 to achieve the objective of improving the display quality of the organic light emitting diode display panel, thereby improving the product yield of the organic light emitting diode display panel, and improving the shipment rate of the organic light emitting diode display panel.

Correspondingly, the present application further provides an OLED display device, including the OLED display panel 1. The OLED display panel includes a substrate 10, a plurality of signal lines 20 and at least one spare line 30 disposed on the substrate 10, wherein the signal lines 20 are at a different layer from the spare line 30. wherein a projection of the spare line 30 on the substrate 10 possesses at least two overlapping points with a projection of any of the signal lines 20 on the substrate 10. For the specific structure of the OLED display panel 1, refer to the previous embodiments and details are not described herein, again.

The organic light emitting diode display panel and the display device provided by the embodiments of the present application are described in detail. The principles and implementations of the present application are described in the specific examples. The description of the above embodiments is only for helping to understand the present application. Meanwhile, those skilled in the art will be able to change the specific embodiments and the scope of the application according to the idea of the present application. In conclusion, the content of the specification should not be construed as limiting the present application.

What is claimed is:

1. An organic light emitting diode display panel, including:
a substrate, a plurality of signal lines and at least one spare line disposed on the substrate, wherein the signal lines are at a different layer from the spare line;
wherein a projection of the spare line on the substrate possesses at least two overlapping points with a projection of any of the signal lines on the substrate;
the spare signal line is a ring structure or a semi-ring structure; and
an insulating layer is disposed between the signal lines and the spare line to insulate the signal lines from the spare line.

2. The organic light emitting diode display panel according to claim 1, wherein a plurality of preset connection points are disposed on the spare line, and the projection of any of the signal lines on the substrate overlaps a projection of the two preset connection points on the substrate, and when any of the signal lines is disconnected, the disconnected signal line is electrically connected to the spare line via the preset connection points at the overlapping points, so that the disconnected signal line works normally through the spare line.

3. The organic light emitting diode display panel according to claim 2, wherein the spare line includes a first portion and a second portion, and a projection of each of the signal lines on the substrate intersects the first portion and the second portion, and the first portion and the second portion are disposed opposite to each other.

4. The organic light emitting diode display panel according to claim 3, wherein the preset connection points include a plurality of first sub preset connection points and a plurality of second sub preset connection points;
the first sub preset connection points are disposed on the first portion along an arrangement direction of the signal lines, and the second sub preset connection points are disposed on the second portion along an arrangement direction of the signal lines.

5. The organic light emitting diode display panel according to claim 4, wherein the spare line further includes a connection portion for connecting the first portion and the second portion, and the connection portion includes a first sub connection portion and a second sub connection portion, and the first sub connection portion and the second sub connection portion are respectively located on two sides of the plurality of signal lines.

6. The organic light emitting diode display panel according to claim 4, wherein the spare line further includes a connection portion for connecting the first portion and the second portion, and the connection portion is located on either side of the plurality of signal lines.

7. The organic light emitting diode display panel according to claim 1, wherein a number of the spare lines is greater than or equal to half a number of the signal lines.

8. The organic light emitting diode display panel according to claim 7, wherein the plurality of the spare lines is disposed at a same layer and is insulated from one another.

9. The organic light emitting diode display panel according to claim 7, wherein the plurality of the spare lines are disposed at different layers.

10. An organic light emitting diode display panel, including:
a substrate, a plurality of signal lines and at least one spare line disposed on the substrate, wherein the signal lines are at a different layer from the spare line;
wherein a projection of the spare line on the substrate possesses at least two overlapping points with a projection of any of the signal lines on the substrate.

11. The organic light emitting diode display panel according to claim 10, wherein a plurality of preset connection points are disposed on the spare line, and the projection of any of the signal lines on the substrate overlaps a projection of the two preset connection points on the substrate, and when any of the signal lines is disconnected, the disconnected signal line is electrically connected to the spare line via the preset connection points at the overlapping points, so that the disconnected signal line works normally through the spare line.

12. The organic light emitting diode display panel according to claim 11, wherein the spare line includes a first portion and a second portion, and a projection of each of the signal lines on the substrate intersects the first portion and the second portion, and the first portion and the second portion are disposed opposite to each other.

13. The organic light emitting diode display panel according to claim 12, wherein the preset connection points include a plurality of first sub preset connection points and a plurality of second sub preset connection points;
the first sub preset connection points are disposed on the first portion along an arrangement direction of the signal lines, and the second sub preset connection points are disposed on the second portion along an arrangement direction of the signal lines.

14. The organic light emitting diode display panel according to claim 13, wherein the spare line further includes a connection portion for connecting the first portion and the second portion, and the connection portion includes a first sub connection portion and a second sub connection portion, and the first sub connection portion and the second sub connection portion are respectively located on two sides of the plurality of signal lines.

15. The organic light emitting diode display panel according to claim 13, wherein the spare line further includes a connection portion for connecting the first portion and the second portion, and the connection portion is located on either side of the plurality of signal lines.

16. The organic light emitting diode display panel according to claim 10, wherein an insulating layer is disposed between the signal lines and the spare line to insulate the signal lines from the spare line.

17. The organic light emitting diode display panel according to claim 10, wherein a number of the spare lines is greater than or equal to half a number of the signal lines.

18. The organic light emitting diode display panel according to claim 17, wherein the plurality of the spare lines is disposed at a same layer and is insulated from one another.

19. The organic light emitting diode display panel according to claim 17, wherein the plurality of the spare lines are disposed at different layers.

20. The organic light emitting diode display panel according to claim 19, wherein projections of the spare lines on the substrate overlap.
